(19) United States
(12) Patent Application Publication
(10) Pub. No.: US 2006/0223334 A1
(43) Pub. Date: Oct. 5, 2006

(54) System for controlling a plurality of lot processes, method for controlling a plurality of lot processes and method for manufacturing a semiconductor device

(76) Inventor: Kazuo Saki, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/389,124

(22) Filed: Mar. 27, 2006

(30) Foreign Application Priority Data
Mar. 28, 2005 (JP) P2005-092736

(51) Int. Cl. G01L 21/30; H01L 21/31; H01L 21/302

(52) U.S. Cl. 438/765; 216/59; 438/715; 156/345.24

(57) ABSTRACT

A system for controlling lot processes, which are executed in parallel, includes: first and second processing tools processing wafers classified into the lots; a transfer tool transferring the wafers from the first to second processing tools; a recipe storage unit storing recipe data including first and second process periods; a determination module determining first abd second starting times so as to minimize a waiting interval between the first and second process periods, based on the recipe data; and a control module controlling the first and second processing tools by starting operations at the first and second starting times, respectively.

### CROSS REFERENCE TO RELATED APPLICATIONS AND INCOORPORATED BY REFERRENCE

The application is based on and claims the benefit of priority from the prior Japanese Patent Applications No. P2005-092736, filed on Mar. 28, 2005; the entire contents of which are incorporated herein by reference.

### BACKGROUND OF THE INVENTION

1. Field of the Invention

The present invention relates to technology for manufacturing a semiconductor device, more particularly, to a system for controlling a plurality of lot processes, a method for controlling a plurality of lot processes and a method for manufacturing a semiconductor device.

2. Description of the Related Art

Recently, gate insulating films have rapidly become thinner in order to improve characteristics of a transistor. As the gate insulating film has become thinner, leakage current, which runs through the gate insulating film, increases. Consequently, there are problems such as deterioration of reliability of a device and an increase in electrical power consumption of a transistor.

In order to solve the problems, an oxy-nitride film, which can improve the dielectric constant and can decrease leakage current, is used as the gate insulating film, instead of a silicone oxide film (SiO₂ film). In a method for forming the oxy-nitride film, a SiO₂ film is fabricated on a substrate, and then the SiO₂ film is nitridated. As the method for nitridating the SiO₂ film, plasma nitridation, in which the nitridating is conducted with radical nitrogen that is excited by plasma, has been the main process, instead of thermally annealing in an atmosphere of nitride monoxide (NO) gas. Plasma nitridation can decrease the density of the Nitrogen (N₂) which causes deteriorating a surface characteristic of a gate insulating film, so as to decrease the density near the surface of the gate insulating film.

The process of forming the oxy-nitride film using plasma nitridation includes three processes: forming a thin SiO₂ film of about 1.5 nm; a nitridation process of the thin SiO₂ film by plasma nitridation, and a post nitridation anneal (PNA) process in a low-pressure atmosphere of oxide (O₂).

In the process of forming the oxy-nitride film by plasma nitridation, Nitrogen is doped into the SiO₂ film by plasma nitridation. However, the Nitrogen does not stably combine with silicon (Si). Therefore when a wafer is left without being thermally annealed in the annealing process, the density of Nitrogen decreases due to loss (elimination) of Nitrogen from the oxy-nitride film.

The phenomenon of Nitrogen loss strongly depends on the environment in which the wafer is left and the time (waiting interval) of leaving the wafer in the environment in the interval between the plasma nitridation process and the annealing process. That is, the loss of Nitrogen progresses with an increase in the density of the water and O₂ in an environment in which the wafer is left. Thus, the density of Nitrogen decreases with an increase in the waiting interval for leaving the wafer without further processing.

In order to prevent loss of Nitrogen, the environment, which surrounds the wafer before the annealing process, is controlled by clustering a system for plasma nitridation and annealing chamber.

However, the waiting interval for leaving the wafer is not controlled, even using the transfer algorithm in earlier technology, since the waiting interval depends on the relationship between a process period (starting time) of the plasma nitridation process and a process period of the annealing process.

For example, when the process period of the plasma nitridation process is shorter than the process period of the annealing process, a waiting interval between completion of the plasma nitridation and starting of the annealing process occurs. Consequently, there is a problem that the density of Nitrogen in the nitride oxide film decreases by leaving the wafer in a transfer chamber.

As described above, although processes have been controlled in processing a plurality of lot in parallel in earlier technology, two processes for continuous processing has not been controlled. Therefore a waiting interval between the two continuous processes occurs.

### SUMMARY OF THE INVENTION

An aspect of the present invention inheres in a system for controlling a plurality of lot processes, which are executed in parallel, the system including: first and second processing tools configured to process a plurality of wafers classified into the plurality of lots; a transfer tool configured to transfer the wafers from the first to second processing tools; a recipe storage unit configured to store recipe data including a first process period by the first processing tool and a second process period by the second processing tool; a determination module configured to determine a first starting time of the first process period and a second starting time of the second process period so as to minimize a waiting interval between completion of the first process period and start of the second process period, based on the recipe data; and a control module configured to control the first and second processing tools by starting operations at the first and second starting times so as to execute the lot processes by the first and second processing tools, respectively.

Another aspect of the present invention inheres in a method for controlling a plurality of lot processes, which are executed in parallel, the method including: determining first and second starting times for first and second processes processing a plurality of wafer s classified into the plurality of lots continuously without exposing the wafers to an atmosphere, so as to minimize a waiting interval between completion of the first process and start of the second process, based on a first process period of the first process and a second process period of the second process defined by recipe data; and starting processing of the first and second processes at the first and second starting times, respectively.

An additional aspect of the present invention inheres in a method for manufacturing a semiconductor device including: determining a first starting time for starting nitridation of an oxide film on a wafer and a second starting time for starting annealing of the nitridated oxide film respectively, so as to minimize a waiting interval between completion of the nitridation and starting of the annealing, based on a first process period of the nitridation and a second process period of the annealing, as defined by a recipe; fabricating the oxide film on the wafer; starting nitridation of the oxide film at the first starting time; and starting annealing of the nitridated oxide film at the second starting time, without exposing the wafer to an atmosphere.

### BRIEF DESCRIPTION OF DRAWINGS

FIG. 1 is a block diagram showing an example of a system for controlling a plurality of lot processes according to an embodiment of the present invention;

FIG. 2 is a graph showing a relationship between a time for leaving a wafer after a plasma nitridation process and the density of nitrogen in a gate insulating film;

FIG. 3(a) is a timing chart showing processing by a first processing tool according to the embodiment of the present invention, when a first process period of the plasma nitridation process is shorter than a second process period of an annealing process;

FIG. 3(b) is a timing chart showing processing by a second processing tool according to the embodiment of the present invention, when the first process period of the plasma nitridation process is shorter than the second process period of the annealing process;

FIG. 4(a) is a timing chart showing processing by the first processing tool according to the embodiment of the present invention, when the first process period of the plasma nitridation process is longer than the second process period of the annealing process;

FIG. 4(b) is a timing chart showing processing by the second processing tool according to the embodiment of the present invention, when the first process period of the plasma nitridation process is longer than the second process period of the annealing process;

FIG. 5 is a flowchart showing an example of a method for controlling a plurality of lot processes according to the embodiment of the present invention;

FIG. 6 is a flowchart showing an example of a method for manufacturing a semiconductor device according to the embodiment of the present invention;

FIG. 7(a) is a timing chart showing processing by the first processing tool according to a modification of the embodiment of the present invention, when the first process period of the plasma nitridation process is shorter than the second process period of the annealing process;

FIG. 7(b) is a timing chart showing the transfer of a wafer by a transfer tool according to the modification of the embodiment of the present invention, when the first process period of the plasma nitridation process is longer than the second process period of the annealing process;

FIG. 7(c) is a timing chart showing processing by the second processing tool according to the modification of the embodiment of the present invention, when the first process period of the plasma nitridation process is shorter than the second process period of the annealing process;

FIG. 8(a) is a timing chart showing processing by the first processing tool according to the modification of the embodiment of the present invention, when the first process period of the plasma nitridation process is longer than the second process period of the annealing process;

FIG. 8(b) is a timing chart showing the transfer of a wafer by the transfer tool according to the modification of the embodiment of the present invention, when the first process period of the plasma nitridation process is longer than the second process period of the annealing process;

FIG. 8(c) is a timing chart showing processing by a second processing tool according to the modification of the embodiment of the present invention, when the first process period of the plasma nitridation process is longer than the second process period of the annealing process;

FIG. 9(a) is a timing chart showing processing by the first processing tool according to a comparative example;

FIG. 9(b) is a timing chart showing processing by the second processing tool according to the comparative example.

### DETAILED DESCRIPTION OF THE INVENTION

An embodiment and a modification of the present invention will be described with reference to the accompanying drawings. It is to be noted that the same or similar reference numerals are applied to the same or similar parts and elements throughout the drawings, and the description of the same or similar parts and elements will be omitted or simplified.

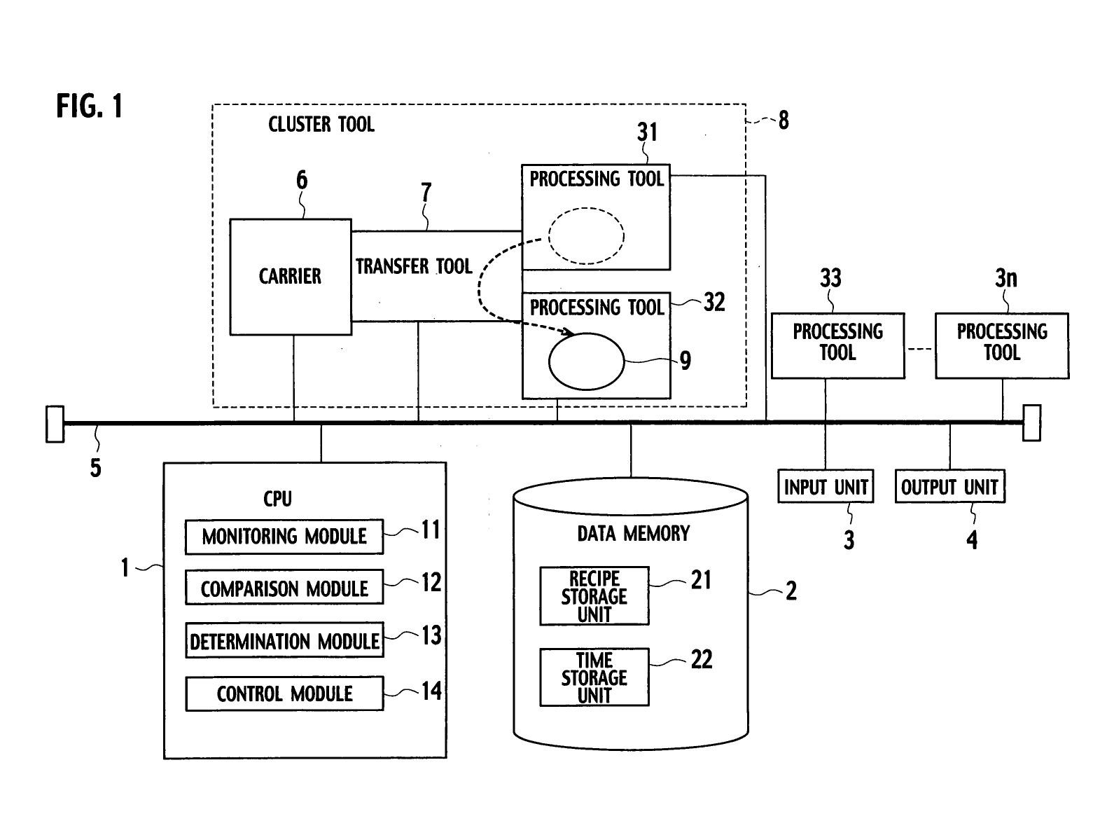

As shown in FIG. 1, a system for controlling a plurality of lot processes according to the embodiment of the present invention, which are executed in parallel, the system includes: a first processing tool 31 and a second processing tool 32 configured to process a plurality of wafers 9 classified into the plurality of lots; a transfer tool 7 configured to transfer the wafers 9 from the first to second processing tools 31 and 32; a recipe storage unit 21 configured to store recipe data including a first process period by the first processing tool 31 and a second process period by the second processing tool 32; a determination module 13 configured to determine a first starting time of the first process period and a second starting time of the second process period so as to minimize a waiting interval between completion of the first process period and start of the second process period, based on the recipe data; and a control module 14 configured to control the first and second processing tools 31 and 32 by starting operations at the first and second starting times so as to execute the lot processes by the first and second processing tools 31 and 32, respectively.

In the system shown in FIG. 1, a central processing unit (CPU) 1, a plurality of (first to n-th) processing tools 31 to 3n (n is a natural number), a data memory 2, an input unit 3, and an output unit 4 are connected with one another through a bus 5.

Each of the first to n-th processing tools 31 to 3n can be a semiconductor manufacturing apparatus such as: an ion implanter; an impurity diffusion system; a thermal oxidation furnace fabricating a SiO₂ film; a chemical vapor deposition (CVD) system depositing a SiO₂ film, a phospho silicate glass (PSG) film, a boron silicate glass (BSG) film, a boro-phospho silicate glass (BPSG) film, a silicon nitride (Si₃N₄) film, a polycrystalline silicon layer and the like; a heat treatment furnace (annealer) for melting (reflowing) a PSG film, a BSG film, a BPSG film and the like; an oxidation system for densifying a CVD silicon oxidation film, another heat treatment furnace forming a silicide film and the like; a sputtering system depositing a metal wiring layer; a vacuum evaporation system; a plating machine to form a metal wiring layer; a chemical mechanical polishing apparatus; a wet or dry etching system etching a surface of a semiconductor substrate; cleaning equipment for removing a resist and cleaning with a solution; a spin coater, an aligner such as a stepper; a dicing system, a bonding system bonding electrodes of a diced semiconductor device (chip) to a lead frame, and the like.

Here, for example, the first processing tool 31 is a plasma nitridation system, and the second processing tool 32 is an annealing chamber. The first and second processing tools 31 and 32 are connected to a carrier 6 and the transfer tool 7, respectively. The carrier 6 carries a wafer carrier. A load lock chamber or the like can be used as the carrier 6. The transfer tool 7 transfers the wafer 9 from the first processing tool 31 to the second processing tool 32, in a controlled environment. A transfer camber or the like can be used as the transfer tool 7. The first and second processing tools 31 and 32, the carrier 6 and the transfer tool 7 are combined with one another as a cluster tool.

As described earlier, forming the oxy-nitride film by plasma nitridation includes, for example, three processes: fabricating a thin SiO₂ film by thermal oxidation; a nitridation process of the thin SiO₂ film by plasma nitridation, and a PNA process in a low pressure atmosphere of O₂. In forming the oxy-nitride film by plasma nitridation, the Nitrogen doped into the SiO₂ film by plasma nitridation, does not combine stably with Si.

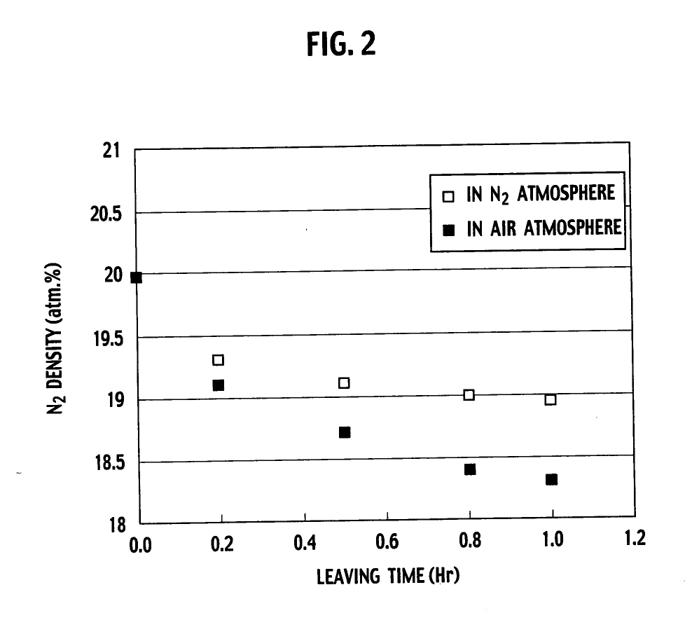

FIG. 2 shows a result of analyzing Nitrogen in the film using X-ray Photoelectron Spectroscopy (XPS). As shown in FIG. 2, the density of Nitrogen decrease with loss of Nitrogen from the oxy-nitride film, when the oxy-nitride film is left without thermal annealing in a PNA process.

The density loss phenomenon strongly depends on the environment where the oxy-nitride film is left and the time the oxy-nitride film is left in the environment. That is, as shown in comparison in an atmosphere of Nitrogen with an atmosphere of air in FIG. 2, the loss of Nitrogen progresses with an increase of the density of the water and O₂ when the wafer is left in such an environment. Furthermore, the density of Nitrogen decreases with an increase in the waiting interval for leaving the wafer.

As shown in FIG. 1, the wafer 9 is placed in a controlled Nitrogen environment after the plasma nitridation process and before the annealing process, so as to avoid exposing the wafer to the atmosphere by clustering the first processing tool (plasma nitridation system) 31, and the second processing tool (annealing chamber) 32. Consequently, it is possible to suppress a decrease in the density of the water and O₂ in the environment where the wafer 9 is left, and to suppress a decrease in the density of Nitrogen in the oxy-nitride film due to the surrounding environment.

The CPU 1 includes a monitoring module 11, a comparison module 12, the determination module 13 and the control module 14. The monitoring module 11 monitors (determines) whether the wafer 9 is processed within the cambers of each of the first and second processing tools 31 and 32, respectively. That is, the monitoring module 11 monitors the utilization states of the first and second processing tools 31 and 32.

The comparison module 12 reads recipe data from the recipe storage unit 21 in the data memory 2. The comparison module 12 then compares a first process period for a plasma nitridation process with a second process period for the annealing process, instantly after the plasma nitridation process. The first and second process periods are described in the recipe data.

The determination module 13 reads the recipe data from the recipe storage unit 21 in the data memory 2. The determination module 13 then determines first and second starting times of each of the first and second process periods by the first and second processing tools 31 and 32, so as to minimize a wafer waiting interval between the first and second process periods, based on the first process period for the plasma nitridation by the first processing tool 31, and the second process period for the annealing process by the second processing tool 32 as described in the recipe data respectively.

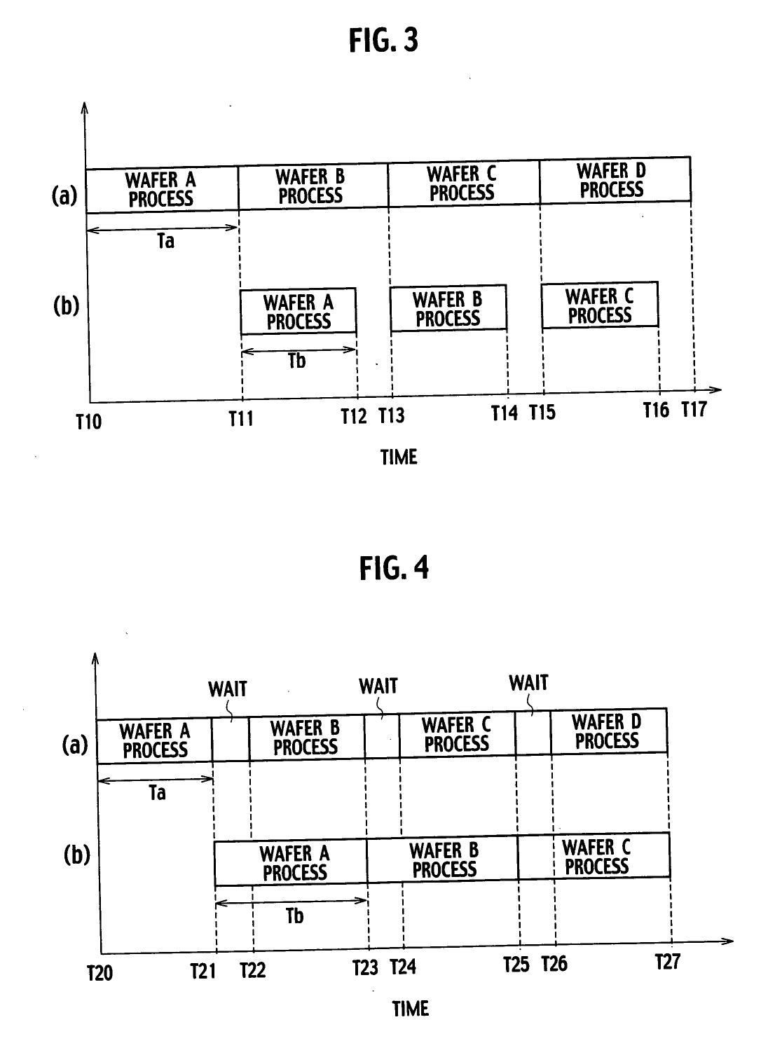

FIGS. 3(a) and 3(b) show an example of process periods when the first process period Tₐ by the first processing tool 31 is longer than the second process period T_{b} by the second processing tool 32. Note that regarding a transfer period transferring a wafer between the first and second processing tools 31 and 32 will be identified below, since the explanation is omitted here.

In this case, if the first and second processing tools 31 and 32 are set so as to start processing when the wafers A, B, C and D are carried into the first and second processing tools 31 and 32, the determination module 13 does not need to determine starting times of the first and second processing tools 31 and 32.

That is, the wafers A, B, C and D are carried into the first processing tool 31, respectively, at times T₁₀, T₁₁, T₁₃ and T₁₅. The control module 14 controls the first processing tool 31 to automatically start processing the wafers A, B, C and D, respectively, when the monitoring module 11 determines that the wafers A, B, C and D are within a chamber of the first processing tool 31.

Then, the wafers A, B, C and D are carried into the second processing tool 32, respectively, after the end times T₁₁, T₁₃, T₁₅ and T₁₇ of processing by the first processing tool 31. The first processing tool 31 controls the second processing tool 32 to automatically start a processing immediately when the monitoring module 11 determines that the wafers A, B, C and D are within a chamber of the second processing tool. That is, there is no waiting interval between the first and second processing tools 31 and 32.

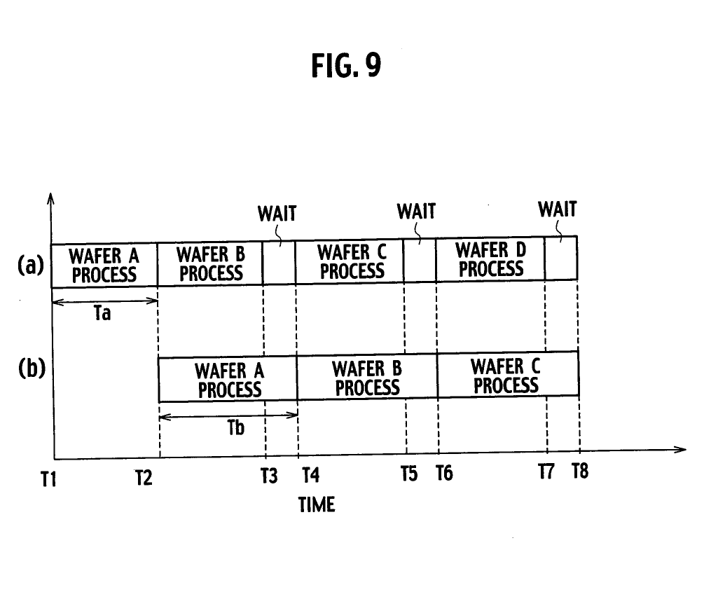

On the other hand, FIGS. 9(a) and 9(b) show a comparative example of process periods when the first process period Tₐ by the first processing tool 31 is shorter than the second process period T_{b} by the second processing tool 32.

Wafers A, B, C and D are carried into the first processing tool 31 at times T₁, T₂, T₄ and T₆, the first processing tool 31 starts processing. However, when the first processing tool 31 completes processing of the wafers B, C and D at times T₃, T₅ and T₇, the second processing tool 32 has not finished processing the wafers A, B and C. Therefore, waiting intervals T₃ to T₄, T₅ to T₆, and T₇ to T₈ from the times T₃, T₅ and T₇ for completing processing with the first processing tool 31 to the times T₄, T₆ and T₈ for starting processing with the second processing tool 32 occur. Consequently, the wafers B, C and D are left within the first processing tool 31 or within the transfer tool 7.

As shown in FIGS. 4(a) and 4(b), the determination module 13, shown in FIG. 1, determines first starting times T₂₀, T₂₂, T₂₄ and T₂₆ for starting processing by the first processing tool 31, and second starting times T₂₁, T₂₃ and T₂₅ for starting processing with the second processing tool, so as to minimize a waiting interval between the first and second processing tools 31 and 32, when the first process period Tₐ by the first processing tool 31 is shorter than the second process period T_{b} by the second processing tool 32. For example, the determination module 13 determines the first starting times T₂₀, T₂₂, T₂₄ and T₂₆ and the second starting times T₂₁, T₂₃ and T₂₅ so as to complete processing by the first processing tool 31 while the second processing tool 32 starts processing at times T₂₁, T₂₃ and T₂₅.

As shown in FIG. 4(a), even if the wafers B, C and D are transferred to the first processing tool 31 at times T₂₁, T₂₃ and T₂₅, and the monitoring module 11 determines that the wafers B, C and D are within the first processing tool 31, the control module 14 controls the first processing tool 31 to wait till the first times T₂₂, T₂₄ and T₂₆ are determined by the determination module 13. The control module 14 controls the first processing tool 31 to start processing at the first starting times T₂₂, T₂₄ and T₂₆. Therefore, a waiting interval for leaving wafers B, C and D between ending processing of the wafers B, C and D in the first processing tool 31 and starting processing with the second processing tool 32 is not generated. Consequently, it is possible to avoid leaving the wafers B, C and D in an atmosphere after completion of processing of the wafers B, C and D in the first processing tool 31.

The CPU 1 further includes a memory manager (not shown). The memory manager controls the data memory 2 for reading and writing in data.

The input unit 3 may be, for example, a keyboard, a mouse, a recognition device such as an optical character reader (OCR), a drawing input device such as an image scanner, or a special input unit such as a voice input device.

The output unit 4 may be a display device such as a liquid crystal display (LCD), CRT display, or a printing device such as an ink jet printer or a laser printer.

The system shown in FIG. 1 further includes an input/output manager (interface) (not shown) connecting the input unit 3, the output unit 4 and so on to the CPU 1.

The data memory 2 shown in FIG. 1 includes: the recipe storage unit 21 storing recipe data of each of the first to n-th processing tools 31 to 3n, and for each of the products to be manufactured; and a time storage unit 22 storing starting times of the first to n-th processing tools 31 to 3n and transfer starting times for transferring wafers between the first to n-th processing tools 31 to 3n and the like, as determined by the determination module 13.

The data memory 2 includes read-only memory (ROM) and random-access memory (RAM). The ROM stores a program executed by the CPU 1 (the details of the program are described later). The RAM serves as a temporary data memory for storing data used in executing a program by the CPU 1, and used as a working domain. As the data memory 2, a flexible disk, a CD-ROM, a MO disk, etc. can be used.

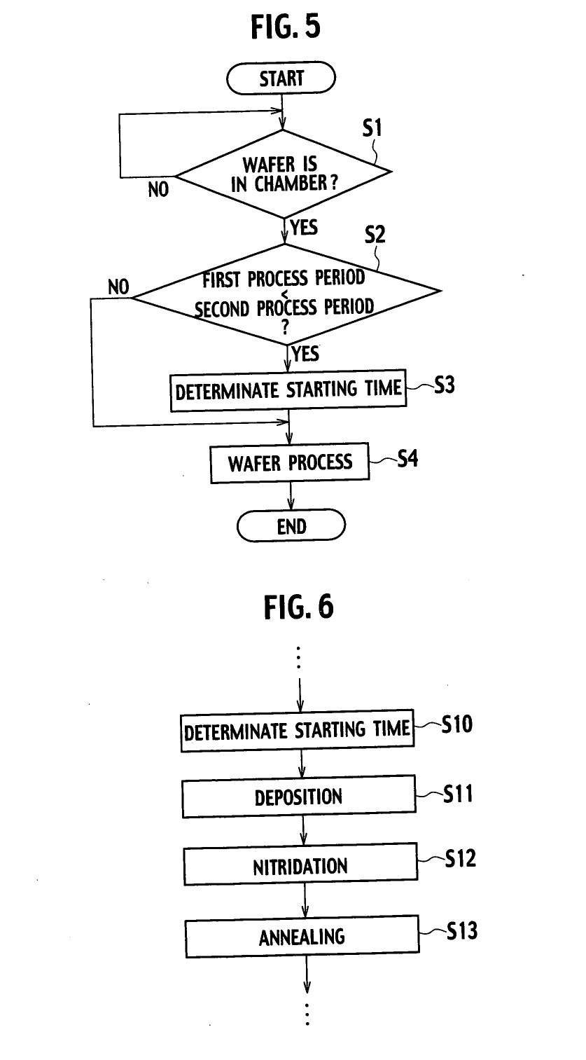

Next, a method for controlling a plurality of lot processes according to the embodiment of the present invention will be described referring to the flowchart of FIG. 5.

In step S1, the monitoring module 11 determines whether the wafers 9 are carried into a chamber in each of the first and second processing tools 31 and 32. When the wafers 9 are in the first and second processing tools 31 and 32, the procedure advances to step S2. On the other hand, if no wafer is either the first or second processing tools 31 and 32, the monitoring module 11 continues monitoring the chambers in the first and second processing tools 31 and 32.

In step S2, the comparison module 12 reads recipe data from the recipe storage unit 21. Then, the comparison module 12 compares a first process period Tₐ of the first processing tool 31 with a second process period T_{b} of the second processing tool 32, as described in the recipe data. As a result of the comparison, as shown in FIGS. 3(a) and 3(b), in the case where the first process period Tₐ of the first processing tool 31 is longer than the second process period T_{b} of the second processing tool 32, the first and second processing tools 31 and 32 may automatically start processing, one by one, when the monitoring module 11 determines that the wafers 9 are in chambers of the first and second processing tools 31 and 32. For this reasons, the procedure may advance to step S4 without determining starting times of step S3.

On the other hand, as a result of the comparison of step S2, when the first process period Tₐ of the first processing tool 31 is shorter than the second process period T_{b} of the second processing tool 32, the procedure advances to step S3.

In step S3, the determination module 13 reads recipe data for the plasma nitridation process using the first processing tool 31, and another recipe data for the annealing process using the second processing tool 32, instantly after end of the plasma nitridation process, from the recipe storage unit 21. As shown in FIGS. 4(a) and 4(b), the determination module 13 determines first starting times T₂₀, T₂₂, T₂₄ and T₂₆ for starting processing with the first processing tool 31, and second starting times T₂₁, T₂₃ and T₂₅ for starting processing with the second processing tool 32, so as to minimize the wafer waiting interval between the first and second processing tools 31 and 32, based on the first process period Tₐ of the plasma nitridation process and the second process period T_{b} of the annealing process, as described in the recipe data.

In step S4, the control module 14 controls the first and second processing tools 31 and 32 to start processing, respectively. As shown in FIG. 4(a), when the first process period Tₐ of the first processing tool 31 is shorter than the second process period T_{b} of the second processing tool 32, the control module 14 controls the first processing tool 31 to wait until the first starting times T₂₂, T₂₄ and T₂₆ are determined by the determination module 13, and to start processing at the first times T₂₂, T₂₄ and T₂₆. That is, when the first processing tool 31 ends processing at times T₂₁, T₂₃, T₂₅ and T₂₇, the wafers 9 are immediately transferred to the second processing tool 32 without being exposed to the atmosphere, and the second processing tool 32 starts processing continuously.

According to the embodiment of the present invention in continuous processes including the plasma nitridation process and the annealing process, it is possible to minimize a waiting interval from the end of the nitridation of the SiO₂ film by the first processing tool 31 to the start of the annealing process by the second processing tool 32. Thereby, it is possible to suppress a decrease in the density of Nitrogen in the oxy-nitride film within the transfer tool 7 to a minimum, and it is possible to manage processes constantly without depending on the time of a process recipe. That is, it is possible to minimize a time from the ending time of the plasma nitridation process to the starting time of the annealing process, and it is possible to suppress loss of Nitrogen from the SiO₂ film.

Note that, as shown in FIGS. 3(a) and 3(b), when the first process period Tₐ of the first processing tool 31 is shorter than the second process period T_{b} of the second processing tool 32, the determination module 13 does not need to determine the first and second starting times. However, if the first and second processing tools 31 and 32 are not set to automatically start processing, one by one, when the monitoring module 11 determines that the wafers 9 are in chambers of the first and second processing tools 31 and 32, the determination module 13 may determines the first starting times T₁₀, T₁₁, T₁₃ and T₁₅ for starting processing with the first processing tool 31, and the second starting times T₁₁, T₁₃ and T₁₅ for starting processing with the second processing tool 32.

Furthermore, the determination module 13 determines the second starting times T₂₁, T₂₃ and T₂₅ for starting processing with the second processing tool 32. However, the second processing tool 32 may start processing when the monitoring module 11 determines that a wafer 9 is transferred into the second processing tool 32. For this reasons, the starting times T₂₁, T₂₃ and T₂₅ for processing wafers, using the second processing tool 32, do not need to be determined.

The procedures shown in FIG. 5 can be executed by controlling the CPU 1 with a program, the algorisms thereof defining the procedures. The program can be stored in a computer-readable storage medium. The procedures of the method of generating mask data can be performed by reading the program from the computer-readable storage medium to the data memory 2 or the like.

Here, the “computer-readable storage medium” means any media that can store a program, including, e.g., external memory units, semiconductor memories, magnetic disks, optical disks, magneto-optical disks, magnetic tape, and the like for a computer. To be more specific, the “computer-readable storage media” include flexible disks, CD-ROMs, MO disks, and the like. For example, the main body of the system can be configured to incorporate a flexible disk drive and an optical disk drive, or to be externally connected thereto. A flexible disk is inserted into the flexible disk drive, a CD-ROM is inserted into the optical disk drive, and then a given readout operation is executed, whereby programs stored in these storage media can be installed on the data memory 2. In addition, by connecting given drives to the system, it is also possible to use, for example, a ROM or magnetic tape. Furthermore, it is possible to store a program in another program storage device via a network, such as the Internet.

Next, an example of a method for manufacturing a semiconductor device including a method for processing a plurality of lots) according to the embodiment of the present invention will be described with reference to the flowchart of FIG. 6.

Note that processes forming a gate insulating film (oxy-nitride film) for a logic LSI are described in FIG. 6. However, a method for manufacturing a semiconductor device actually includes various and many processes not illustrated in FIG. 6. The manufacturing method described below is one example, and it is feasible to substitute modifications by various other manufacturing methods.

In step S10, the monitoring module 11 monitors the wafer 9 in step S1 of FIG. 5, and the comparison module 12 compares the first and second process periods with each other in step S2. Furthermore, the determination module 13 determines a first starting time for nitridating a SiO₂ film and a second starting time for annealing the nitridated SiO₂ film, so as to minimize a wafer waiting interval between the nitridation of the SiO₂ film and the annealing of the nitridated SiO₂ film, based on the first process period for the nitridation of the SiO₂ film of step S3 and the second process period for annealing of the nitridated SiO₂ film.

In step S11, a thermal oxide film (SiO₂ film) for a gate insulating film is provided on a semiconductor substrate by thermal oxidation with an oxidation system such as, for example, a third processing tool 33 shown in FIG. 1 from among the third to n-th processing tools 33 to 3n.

In step S12, the SiO₂ film is nitridated by plasma nitridation using the first processing tool (plasma nitridation system) 31. Here, the first processing tool 31 waits until a first starting time is determined by the determination module 13, and then starts processing at the first starting time.

In step S13, the transfer tool 7 transfers the wafer 9 to the second processing tool 32 without exposing the wafer 9 to an atmosphere. Then, a low-pressure PNA process is carried out in an O₂ atmosphere using the second processing tool 32. Here, the second processing tool 32 starts processing immediately after the first processing tool 31 has stopped processing the wafer 9. Consequently, an oxy-nitride film for the gate insulating film is fabricated on the semiconductor substrate.

According to a method for manufacturing a semiconductor device according to the embodiment of the present invention, since a wafer waiting interval between the plasma nitridation process of step S12 and the annealing process of step S13 is minimized, it is possible to suppress loss of Nitrogen from the oxy-nitride film. Therefore, manufacturing yield will be improved.

Note that the nitridation of the SiO₂ film using the first processing tool 31 of step S12 and the annealing of the SiO₂ film using the second processing tool 32 of step S13 processes a plurality of lots in parallel with each other.

### MODIFICATION

In a modification of the embodiment of the present invention, a method for controlling a plurality of lot processes, by taking into account a transfer period for the wafer 9, shown in FIG. 1. will be described. When the first and second processing tools 31 and 32 process the wafer 9 continuously, a transfer period for transferring the wafer 9 from the first processing tool 31 to the second processing tool 32 with the transfer tool 7 is a practical consideration. When a wafer waiting interval between the first and second processing tools 31 and 32 occurs, the wafer 9 is left within the first processing tool 31 or within the transfer tool 7.

The comparison module 12 shown in FIG. 1 compares a first process period of the first processing tool 31 with a sum of a second process period of the second processing tool 32 and the transfer period of the wafer 9, when the wafer 9 is left inside the first processing tool 31.

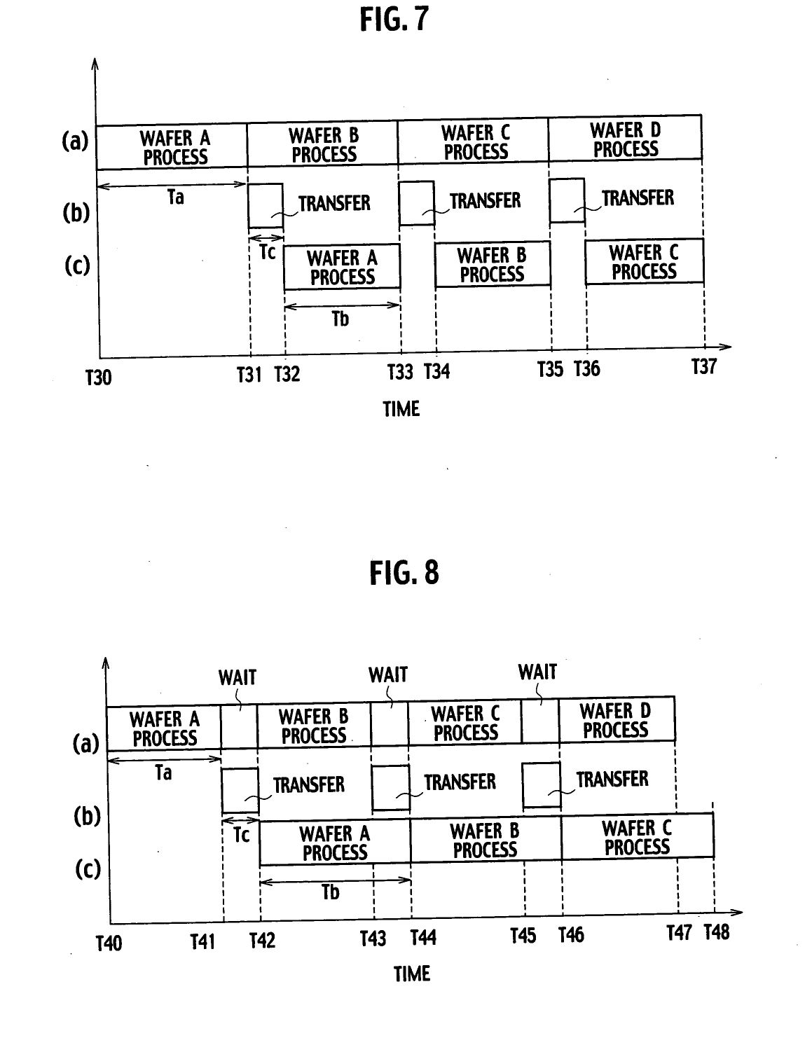

As shown in FIGS. 7(a) to 7(c), when the first process period Tₐ of the first processing tool 31 is longer than the sum (T_{b}+T_{c}) of the second process period T_{b} of the second processing tool 32 and the transfer period T_{c} of the wafer 9, the wafer 9 is transferred at times T₃₁, T₃₃ and T₃₅ immediately after processing by the first processing tool 31 has ended. Therefore, no wafer waiting interval occurs.

On the other hand, when the first process period Tₐ of the first processing tool 31 is shorter than the sum (T_{b}+T_{c}) of the second process period T_{b} of the second processing tool 32 and the transfer period T_{c} of the wafer 9, a wafer waiting interval from ending of processing by the first processing tool 31 to start of processing by the second processing tool 32 occurs.

The determination module 13, shown in FIG. 1, takes into account the transfer period T_{c} of the wafer from the first processing tool 31 to the second processing tool 32 by the transfer tool 7. As shown in FIGS. 8(a) to 8(c), the determination module 13 determines first starting times T₄₂, T₄₄ and T₄₆ by the first processing tool 31, transfer starting times T₄₁, T₄₃ and T₄₅ of the wafer, second starting times T₄₂, T₄₄ and T₄₆ for processing by the second processing tool 32, so as to transfer the wafer 9 to the second processing tool 32 and then process the wafer 9 therein immediately after ending wafer processing by the first processing tool 31.

According to the modification of the embodiment of the present invention, in continuous processes including plasma nitridation and annealing, it is possible to minimize a wafer waiting interval between the end of the nitridation of the SiO₂ film by the first processing tool 31 and the start of annealing by the second processing tool by taking into account the transfer period of the wafer 9. Therefore it is possible to suppress a decrease in the density of Nitrogen in the oxy-nitride film to a minimum while the wafer 9 is in the transfer tool 7, and it is possible to manage the processes constantly without depending on a time for a process recipe.

That is, it is possible to minimize a time between ending the plasma nitridation process and starting the annealing process, and thereby it is possible to suppress loss of Nitrogen from the SiO₂ film.

### OTHER EMBODIMENTS

Various modifications will become possible for those skilled in the art after receiving the teachings of the present disclosure without departing from the scope thereof.

In the embodiment, an example of forming an oxy-nitride film by nitridating and annealing SiO₂ film has been described. However, the oxide film is not limited to an SiO₂ film. An oxide film containing at least an element of metal such as aluminum (Al), zirconium (Zr), hafnium (Hf), titanium (Ti), tantalum (Ta) and lanthanum (La), can be used. For the oxide film, hafnium oxide film (hafnia; HfO2), zirconium oxide film (ZrO₂), aluminum oxide film (alumina; Al₂O₃), titanium oxide film (TiO₂), tantalum oxide film (Ta₂O₅), lanthanum oxide film (La₂O₃) and the like, can be used.

An alloy of Hf, Zr, Al, Ti, Ta or La can also be used as the oxide film. As the oxide film of the alloy, for example, aluminum hafnium oxide (HfₓAl_{y}O_{z}), zirconium hafnium oxide (HfₓZr_{y}O_{z}), aluminum zirconium oxide (ZrₓAl_{y}O_{z}), aluminum titanium oxide (TiₓAl_{y}O_{z}), zirconium titanium oxide (TiₓZr_{y}O_{z}), hafnium titanium oxide (TiₓHf_{y}O_{z}), aluminum tantalum oxide (TaₓAl_{y}O_{z}), zirconium tantalum oxide (TaₓZr_{y}O_{z}), hafnium tantalum oxide (TaₓHf_{y}O_{z}), titanium tantalum oxide (TaₓTi_{y}O_{z}), aluminum lanthanum oxide (LaₓAl_{y}O_{z}), zirconium lanthanum oxide (LaₓZr_{y}O_{z}), hafnium lanthanum oxide (LaₓHf_{y}O_{z}), titanium lanthanum oxide (LaₓTi_{y}O_{z}) tantalum lanthanum oxide (LaₓTa_{y}O_{z}) and the like, can be used.

Further, the foregoing embodiment describes an example of a method for manufacturing a semiconductor device. It should be easily understood from the above descriptions that the present invention can also be applied to a method for manufacturing electronic devices including a liquid crystal device, a magnetic storage medium, an optical storage medium, a thin-film magnetic head, a superconductive element, and the like.

What is claimed is:

1. A system for controlling a plurality of lot processes, which are executed in parallel, the system comprising:
first and second processing tools configured to process a plurality of wafers classified into the plurality of lots;
a transfer tool configured to transfer the wafers from the first to second processing tools;
a recipe storage unit configured to store recipe data including a first process period by the first processing tool and a second process period by the second processing tool;
a determination module configured to determine a first starting time of the first process period and a second starting time of the second process period so as to minimize a waiting interval between completion of the first process period and start of the second process period, based on the recipe data; and
a control module configured to control the first and second processing tools by starting operations at the first and second starting times so as to execute the lot processes by the first and second processing tools, respectively.

2. The system of claim 1, wherein the first processing tool is a plasma nitridation system, and the second processing tool is an annealing chamber.

3. The system of claim 1, further comprising a comparison module configured to compare the first and second process periods with each other.

4. The system of claim 3, wherein the determination module determines the first and second starting times so as to start processing immediately with the second processing tool after completion of processing with the first processing tool, when the first process period is shorter than the second process period.

5. The system of claim 3, wherein the control module controls the first and second processing tools to start processing in a period when the wafers are carried into the first and second processing tools, respectively, when the first process period is longer than the second process period.

6. The system of claim 1, wherein the transfer tool transfers the wafers without exposing the wafers an atmosphere, by controlling an environment surrounding the wafers.

7. The system of claim 3, wherein the determination module determines the first and second starting times, based on a transfer period during which the wafers are transferred from the first to the second processing tools.

8. The system of claim 7, wherein the comparison module compares the first process period with a sum of the second process period and the transfer period.

9. The system of claim 8, wherein the determination module further determines a transfer starting time of the wafer, so as to start processing immediately with the second processing tool after completion of processing with the first processing tool, when the first process period is shorter than the sum.

10. The system of claim 8, wherein the control module controls the first and second processing tools to start processing instantly after transferring the wafers to the first and second processing tools, respectively, when the first process period is longer than the sum.

11. The system of claim 1, further comprising a monitoring module configured to monitor utilization states of the first and second processing tools.

12. A method for controlling a plurality of lot processes, which are executed in parallel, the method comprising:
determining first and second starting times for first and second processes processing a plurality of wafer s classified into the plurality of lots continuously without exposing the wafers to an atmosphere, so as to minimize a waiting interval between completion of the first process and start of the second process, based on a first process period of the first process and a second process period of the second process defined by recipe data; and
starting processing of the first and second processes at the first and second starting times, respectively.

13. The method of claim 12, wherein the first process is a plasma nitridation process, and the second process is an annealing process.

14. The method of claim 12, further comprising:
comparing the first and second process periods with each other.

15. The method of claim 14, further comprising:
determining the first and second starting times, so as to start processing of the second process immediately after completion of processing of the first process, when the first process period is shorter than the second process period.

16. The method of claim 14, further comprising:
starting processing of the first and second processes when the wafers are carried into first and second processing tools for processing in the first and second processes, respectively, when the first process period is longer than the second process period.

17. The method of claim 14, further comprising:
determining the first and second starting times, based on a transfer period for transferring the wafers from the first process to the second process.

18. The method of claim 17, further comprising:
determining a transfer starting time of the wafers, so as to start processing of the second process immediately after completion of processing of the first process, when the first process period is shorter than a sum of the second process period and the transfer period.

19. The method of claim 17, further comprising:
starting the first and second processes, respectively, instantly after transferring the wafers to first and second processing tools for processing in the first and second processes, respectively, when the first process period is longer than a sum of the second process period and the transfer period.

20. A method for manufacturing a semiconductor device comprising:
determining a first starting time for starting nitridation of an oxide film on a wafer and a second starting time for starting annealing of the nitridated oxide film respectively, so as to minimize a waiting interval between completion of the nitridation and starting of the annealing, based on a first process period of the nitridation and a second process period of the annealing, as defined by a recipe;
fabricating the oxide film on the wafer;
starting nitridation of the oxide film at the first starting time; and
starting annealing of the nitridated oxide film at the second starting time, without exposing the wafer to an atmosphere.
